(19) United States
(12) Patent Application Publication
(10) Pub. No.: US 2018/0051378 A1
(43) Pub. Date: Feb. 22, 2018

(54) WET ETCHING EQUIPMENT AND WET ETCHING METHOD

(71) Applicant: BOE Technology Group Co., Ltd., Beijing (CN)

(72) Inventor: Dapeng Xue, Beijing (CN)

(21) Appl. No.: 15/534,587

(22) PCT Filed: May 25, 2016
(86) PCT No.: PCT/CN2016/083270

§ 371 Date: Jun. 9, 2017

(30) Foreign Application Priority Data
Mar. 7, 2016 (CN) 201610128624.0

(51) Int. Cl. C23F 1/08; C23F 1/46; H01L 21/67; H01L 21/677

(52) U.S. Cl. CPC C23F 1/08; H01L 21/677; H01L 21/6708; C23F 1/46

(57) ABSTRACT

Embodiments of the present disclosure disclose a wet etching equipment and a wet etching method. The wet etching equipment includes a metal ion concentration adjusting device configured to adjust the concentration of metal ions in an etching solution, a sprinkler which is connected to the metal ion concentration adjusting device and configured to spray the etching solution. Embodiments of the present disclosure also disclose a wet etching method, comprising steps as follows: adjusting a concentration of metal ions in an etching solution so that an etching rate of a metal to be etched is kept stable; spraying the adjusted etching solution onto the metal to be etched.

### CROSS-REFERENCE TO RELATED APPLICATION

This application is a Section 371 National Stage Application of International Application No. PCT/CN2016/083270, filed on 25 May 2016, which has not yet published, and claims priority to Chinese Patent Application No. 201610128624.0 filed on Mar. 7, 2016 in the State Intellectual Property Office of China, the disclosures of which are incorporated herein by reference.

### FIELD OF THE INVENTION

Embodiments of the present disclosure relates to the display field, specifically relates to a wet etching equipment and a wet etching method.

### DESCRIPTION OF THE RELATED ART

In the field of semiconductor display, metal wires used in a conventional array substrate mainly include Mo, Al or alloys thereof, while the performance of the entire array substrate is highly correlated with the materials used in its various layers. With the development and requirements of a large size, a high resolution and a high driving frequency of display terminals, conventional metal wires (such as Mo, Al or alloys thereof) are unable to meet the design requirements due to their relatively high resistivity.

Compared with conventional metal wires, a Cu (copper) wire has a lower resistivity and a good resistance to electromigration, thereby attracting more and more panel developers and major materials manufacturers to perform researches and developments thereon. However, in an etching process, after a Reactive Ion Etching (RIE) or an Inductively Coupled Plasma (ICP) etching, the metal Cu will create copper fluoride (CuFx) and copper chloride (CuClx), which are in a solid state at a temperature of 200° C. or lower and which do not vaporize. Therefore the metal Cu cannot be patterned by a dry etching as metal Mo and Al. Therefore, an etching of metal Cu is mainly performed with a wet etching method at present, and the etching solution for Cu is usually a H₂O₂ system. A reaction principle of the Cu etching is presented as follows:

Cu+H₂O₂+2H⁺→Cu²⁺+2H₂O;

2H₂O₂→2H₂O+O₂↑;

in which, in processes of the above reaction, the relationship between the concentration of Cu ions in the etching solution and the etching rate is shown in FIG. 1. As can be seen from FIG. 1, the etching rate increases rapidly with a increase of Cu ions until the etching rate becomes stable, that is, when the concentration of Cu ions does not reach a concentration value A (i.e. the etching rate saturation concentration value), the Cu ions serve as a catalyst to accelerate decomposition of H₂O₂; before the concentration of Cu ions reaches the concentration value A, with the increase of Cu ion concentration, the reaction process is accelerated, such that the etching rate becomes faster and faster, and the etching rate tends to be stable until the Cu ion concentration reaches the concentration value A, resulting in that, the etching effect differs much from a sheet to another sheet, with a poor etching stability, which affects a quality of Cu etching seriously, and ultimately affects the performance of the entire product.

### SUMMARY OF THE INVENTION

There is provided a wet etching equipment, comprising:
a metal ion concentration adjusting device configured to adjust the concentration of metal ions in an etching solution;
a sprinkler, which is connected to the metal ion concentration adjusting device and configured to spray the etching solution.

Optionally, the metal ion concentration adjusting device comprises a metal ion source comprising a metallic material, the etching solution being subject to a chemical reaction by a contact with the metallic material so as to adjust the concentration of the metal ions in the etching solution.

Optionally, the metallic material is in a form of powder or granules, and the metal ion source further comprises a carrying container configured to contain the metallic material.

Optionally, the metallic material is in a form of a film and the metal ion source further comprises a carrying substrate configured to carry the metallic material.

Optionally, the metal ion concentration adjusting device comprises at least an adjusting branch, each of the adjusting branches being provided with a metal ion source and a first valve configured to control an on-off switching of its own.

Optionally, the metal ion concentration adjusting device comprises a plurality of adjusting branches.

Optionally, the wet etching equipment further comprises a reservoir, an etching solution recovery device, and an etching branch:

the reservoir is configured to store the etching solution, which comprises an input port configured to input the etching solution and an output port configured to output the etching solution;

the etching solution recovery device is connected to the input port of the reservoir, and is configured to recycle the etching solution sprayed by the sprinkler to the reservoir;

an input port of the etching branch and an input port of the adjusting branch are communicated with the output port of the reservoir, and an output port of the etching branch and an output port of the adjusting branch are communicated with the sprinkler, a second valve being further provided in the etching branch and configured to adjust the flow rate of the etching solution upon etching a metal to be etched.

Optionally, the etching solution recovery device comprises an etching chamber and a return line connecting the etching chamber with the input port of the reservoir, the sprinkler being arranged inside the etching chamber.

Optionally, the wet etching equipment further comprises a filter configured to filter the etching solution inputted to the sprinkler.

Optionally, the wet etching equipment further comprises a metal ion concentration detecting device configured to detect the concentration of the metal ions in the etching solution.

Optionally, the wet etching equipment further comprises a controller configured to control the metal ion concentration adjusting device to adjust the concentration of the metal ions in the etching solution so that the concentration of the metal ions in the etching solution reaches a preset value, and then to spray the adjusted etching solution onto the metal to be etched with the sprinkler.

There is also provided a wet etching method, comprising steps as follows:

adjusting a concentration of metal ions in an etching solution so that an etching rate of a metal to be etched is kept stable;

spraying the adjusted etching solution onto the metal to be etched.

Optionally, the wet etching method further comprises a step before the step of spraying the adjusted etching solution onto the metal to be etched that,

detecting the concentration of the metal ions in the adjusted etch solution, and spraying the adjusted etching solution onto the metal to be etched in a case that the concentration of the metal ions in the adjusted etching solution reaches a preset value.

Optionally, the metal ions comprise Cu ions, and the preset value is greater than or equal to 300 ppm.

### BRIEF DESCRIPTION OF THE DRAWINGS

FIG. 1 is a graph showing the relationship between the concentration of Cu ions in the etching solution and the etching rate in the wet etching process of metallic Cu;

FIG. 2 is a schematic view of a wet etching equipment provided by an embodiment of the present disclosure;

FIG. 3 is a schematic view of a wet etching equipment provided by another embodiment of the present disclosure.

### DETAILED DESCRIPTION OF PREFERRED EMBODIMENTS OF THE INVENTION

Hereinafter, specific embodiments of the present disclosure will be described in further detail with reference to the accompanying drawings and examples. The following examples are intended to illustrate the invention, but are not intended to limit the scope of the invention.

According to a general concept of the present disclosure, there is provided a wet etching equipment and a wet etching method. The wet etching equipment includes a metal ion concentration adjusting device configured to adjust the concentration of metal ions in an etching solution, a sprinkler which is connected to the metal ion concentration adjusting device and configured to spray the etching solution. The wet etching method, comprises steps as follows: adjusting a concentration of metal ions in an etching solution so that an etching rate of a metal to be etched is kept stable; spraying the adjusted etching solution onto the metal to be etched.

The wet etching equipment provided by the present disclosure may avoid an effect of the change of the metal ion concentration in the etching solution on the etching rate, effectively improving the etching stability and thereby improving the yield of the product.

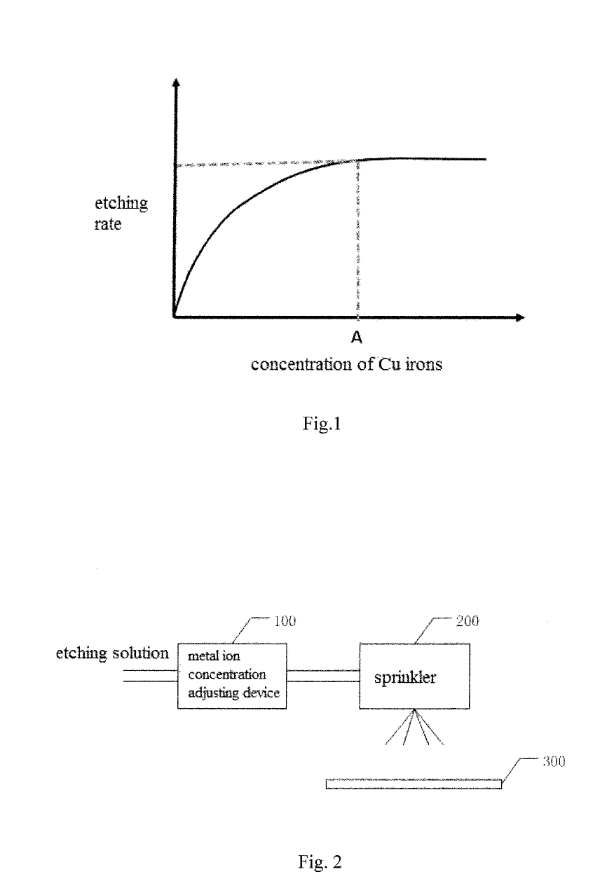

Now referring FIG. 2 which is a schematic view of a wet etching equipment provided by an embodiment of the present disclosure, which comprises:
a metal ion concentration adjusting device 100 configured to adjust the concentration of metal ions in an etching solution;
a sprinkler 200, which is connected to the metal ion concentration adjusting device configured to spray the etching solution.

When an etching process is performed with the above-mentioned wet etching equipment, the etching solution is first passed through the metal ion concentration adjusting device 100, and the concentration of the metal ions in the etching solution is adjusted by the metal ion concentration adjusting device 100 so that the concentration of metal ions in the etching solution reaches a preset value. A metal to be etched on the substrate 300 is etched with the adjusted etching solution sprayed by the sprinkler 200. In the etching process, since the metal ion concentration of the etching solution has reached a preset value before the substrate to be etched is etched with the etching solution, it may avoid an effect of the change of the metal ion concentration in the etching solution on the etching rate, effectively improving the etching stability and thereby improving the yield of the product.

For example, when the concentration of Cu ions in the etching solution reaches the etching rate saturation concentration (about 300 ppm) in the wet etching process for metal Cu using an etching solution of the H₂O₂ system, even if the concentration of Cu ions in the etching solution continues to increase, the etching rate is kept constant. Therefore, when the metal Cu is etched using the wet etching equipment described above, the metal ion concentration adjusting device can adjust the Cu ions concentration in the etching solution so that the concentration of Cu ions in the etching solution reaches the etching rate saturation concentration value. It may avoid an effect of the change of the metal ion concentration in the etching solution on the etching rate, effectively improving the etching stability and in turn improving the yield of the product.

For example, the metal ion concentration adjusting device may comprise a metal ion source comprising a metallic material, the etching solution being subject to a chemical reaction by a contact with the metallic material so as to adjust the concentration of the metal ions in the etching solution. The metal materials of metal ion source and the metal irons in the etching solution whose concentration needs to be adjusted may be of a same element. For example, in the etching process for metal Cu with an etching solution of H₂O₂ system, the metal material in the metal ion source can be metal Cu if the concentration of Cu ions in the etching solution needs to be adjusted.

For example, the metallic material in the metal ion source is in a form of powder or granules. In addition, the metal ion source further comprises a carrying container configured to contain the metallic material.

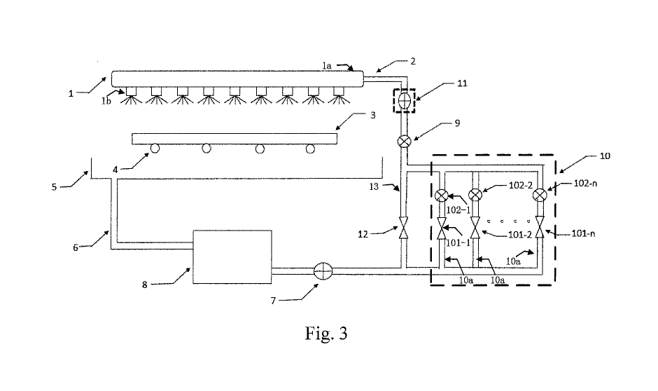

Referring FIG. 3 which is a schematic view of a wet etching equipment according to another embodiment of the present disclosure, the wet etching equipment comprises a sprinkler 1, an etching branch 13, a metal ion concentration adjusting device 10, a reservoir 8, and an etching solution recovery device;

The sprinkler 1 is connected to a supply line 2 and includes a sprinkler tube 1a and a nozzle 1b mounted below the sprinkler tube 1a. The sprinkler 1 performs etching by spraying the etching solution on the metal to be etched on the underlying substrate 3 to be etched;

The reservoir 8 is configured to store the etching solution for recycling, which includes an input port configured to input an etching solution (at a left side of the reservoir 8 in FIG. 3) and an output port configured to output the etching solution (at a right side of the reservoir 8 in FIG. 3);

The etching solution recovery device is connected to the input port of the reservoir 8, for recycling the etching solution sprayed by the sprinkler 1 into the reservoir 8. As shown in FIG. 3, the etching solution recovery device includes an etching chamber 5 and a return line 6 connecting the etching chamber 5 with the input port of the reservoir 8. The sprinkler 1 is arranged inside the etching chamber 5. In addition, a transmission device 4 is arranged in the etching chamber 5 which is configured to convey the substrate 3 to be etched. For example, the transmission device 4 may include a transmission shaft, a transmission gear, a transmission motor or the like.

The metal ion concentration adjusting device 10 comprises at least an adjusting branch 10a, each of which is provided with a metal ion source and a first valve configured to control an on-off switching of its own. For example, the metal ion source may include a carrying container. The carrying container may employ a filter-like structure which contains a metal material in a form of powder or granules. For example, if the metal Cu is subject to a wet etching process, the carrying container may contain the metal Cu material of a powder or granules.

An input port of the etching branch 13 and an input port of the adjusting branch 10a are communicated with the output port of the reservoir 8, and an output port of the etching branch 13 and an output port of the adjusting branch 10a are communicated with the sprinkler 1. That is, each of the adjusting branches is connected in parallel with the etching branch 13, as shown in FIG. 3. The output port of the etching branch 13 is connected to the sprinkler 1 via the supply line 2, and the input port of the etching branch 13 is connected to the output port of the reservoir 8 through a supply pump 7. Similarly, the output port of each of the adjusting branches 10a is connected to the sprinkler 1 via the supply line 2. The input port of each adjusting branch 10a is connected to the output port of the reservoir 8 through the supply pump 7. Further, a second valve 12 is further provided in the etching branch 13 and configured to adjust the flow rate of the etching solution upon etching a metal to be etched on the substrate 3 to be etched.

Optionally, a plurality of adjusting branches may be provided. For example, an n-way adjusting branch may be provided, as shown in FIG. 3, and a metal ion source 102-1 and a first valve 101-1 are arranged on the first adjusting branch, a metal ion source 102-2 and a first valve 101-2 are arranged on the second adjusting branch, . . . and a metal ion source 102-n and a first valve 101-n are arranged on the nth adjusting branch.

In addition, the above-described wet etching equipment may further include a metal ion concentration detecting device 11 configured to detect the metal ion concentration in the etching solution. For example, the metal ion concentration detecting device 11 may be arranged on the supply line 2.

Optionally, in order to avoid damage to the sprinkler 1 by impurities in the etching solution, the above-described wet etching equipment may further include a filter 9 configured to filter the etching solution inputted to the sprinkler. The impurity may be removed from the etching solution by the filter 9. For example, the filter 9 may be arranged on the supply line 2.

For the above-described wet etching equipment, the concentration of the metal ions in the etching solution is firstly adjusted before etching the metal to be etched on the substrate 3 to be etched. Optionally, the first valve 101-1, the first valve 101-2, . . . and the first valve 101-n are opened firstly and the second valve 12 is closed so that the etching solution in the reservoir 8 passes through the metal ion source of each adjusting branch, and is subject to an action with the metal material to produce metal ions, thereby increasing the concentration of the metal ions in the etching solution. The etching solution outputted from each adjusting branch is sequentially passed through the supply line 2, the sprinkler 1, and then recycled to the reservoir 8 by the etching solution recovery device thereby forming a cycle, in which the first valve 101-1, the first valve 101-2, . . . and the first valve 101-n are closed and the second valve 12 is opened when the metal ion concentration detecting device 11 detects that the metal ion concentration in the etching solution reaches the desired preset value, such that the metal to be etched on the substrate 3 to be etched begins to be etched with the adjusted etching solution.

In the embodiments of the present disclosure, the number of adjusting branches in the metal ion concentration adjusting device may be determined according to the specific requirements. The metal ion source may be replaced regularly or in real time as required.

Optionally, in order to improve the degree of automation of the wet etching requirements, the wet etching equipment further comprises a controller configured to control the metal ion concentration adjusting device to adjust the concentration of the metal ions in the etching solution so that the concentration of the metal ions in the etching solution reaches a preset value, and then to spray the adjusted etching solution onto the metal to be etched with the sprinkler.

For example, when the metal Cu is subject to an etching process with an etching solution of a H₂O₂ system, before etching the metal to be etched (i.e., metal Cu) on the substrate 3 to be etched with the above-described wet etching equipment, the controller firstly control the first valve 101-1, the first valve 101-2, . . . , and the first valve 101-n to open, and the second valve 12 to close, and open the supply pump 7. The etching solution passes through the metal ion source of each adjusting branch under the drive of the supply pump 7, and reacts with the metal Cu material in the metal ion source to create Cu ions. The etching solution after the reaction sequentially passes through the supply line 2, the sprinkler 1, and is recycled to the reservoir 8 by the etching solution recovery device, thereby forming a cycle in which the concentration of Cu ions in the etching solution is gradually increased while the metal ion concentration detecting device detects the concentration of the Cu ions in the etching solution in real time. Once the concentration of the Cu ions in the etching solution reaches the etching rate saturation concentration, the controller controls the first valve 101-1, the first valve 101-2, . . . , and the first valve 101-n to close, the second valve 12 to open, and controls the transmission device 4 to transmit the substrate 3 to be etched below the sprinkler 1 and begin to perform etching to the metal to be etched on the substrate 3 to be etched.

In addition, in the present disclosure, the metal ion source may take other forms, for example, its metal material may be in a form of a film, and the metal ion source further comprises a carrying substrate configured to carry the metallic material. For example, a Cu film of a certain thickness may be deposited on a bare glass using a Cu target so as to obtain a Dummy glass. Then the Dummy glass is used to adjust the Cu ion concentration in the etching solution before a tape-out process of chips. The tape-out process is carried out once the concentration of Cu ions in the etching solution reaches the etching rate saturation concentration.

The wet etching equipment provided by the embodiment of the present disclosure can be used in the wet etching process of the metal Cu. By adjusting the concentration of Cu ions in the etching solution to the etching rate saturation value before etching the substrate to be etched, it is possible to avoid the interference of Cu ions to the entire etching reaction when etching the substrate to be etched, that is, it will not change the etching rate, ensuring the stability of the etching and thus improving the product yield. Further, its structure is simple and easy to implement, substantially saving the cost and improving the production efficiency. At the same time, it will greatly increase the service life of the chemical liquid and further save the product cost. In addition, the wet etching equipment of the present disclosure may achieve a real-time and on-line monitoring to the entire etching process.

The embodiments of the present disclosure further provide a wet etching method, comprising steps as follows:

adjusting a concentration of metal ions in an etching solution so that an etching rate of a metal to be etched is kept stable;

spraying the adjusted etching solution onto the metal to be etched.

Optionally, the wet etching method further comprises a step before the step of spraying the adjusted etching solution onto the metal to be etched: detecting the concentration of the metal ions in the adjusted etch solution, and spraying the adjusted etching solution onto the metal to be etched if the concentration of the metal ions in the adjusted etching solution reaches a preset value.

For example, when the metal Cu is subject to an etching process with an etching solution of H₂O₂ system, the concentration of Cu ions in the etching solution may be adjusted, and the above-mentioned preset values may be 300 ppm or more, for example, 310 ppm, 330 ppm, 350 ppm and so on.

The above embodiments are merely illustrative of the present invention and are not to be construed as limiting the invention, and various changes and modifications may be made by those skilled in the art without departing from the spirit and scope of the invention, and therefore all equivalent technical solutions are also within the scope of the present invention, and the scope of patent protection of the present invention is defined by the claims.

1. A wet etching equipment comprising
a metal ion concentration adjusting device configured to adjust the concentration of metal ions in an etching solution;
a sprinkler which is connected to the metal ion concentration adjusting device and configured to spray the etching solution.

2. The wet etching equipment according to claim 1, wherein
the metal ion concentration adjusting device comprises a metal ion source comprising a metallic material, the etching solution being subject to a chemical reaction by a contact with the metallic material so as to adjust the concentration of the metal ions in the etching solution.

3. The wet etching equipment according to claim 2, wherein
the metallic material is in a form of powder or granules, and
wherein the metal ion source further comprises a carrying container configured to contain the metallic material.

4. The wet etching equipment according to claim 2, wherein the metallic material is in a form of a film and
wherein the metal ion source further comprises a carrying substrate configured to carry the metallic material.

5. The wet etching equipment according to claim 2, wherein
the metal ion concentration adjusting device comprises at least an adjusting branch, each of the adjusting branches being provided with a metal ion source and a first valve configured to control an on-off switching of its own.

6. The wet etching equipment according to claim 5, wherein
the metal ion concentration adjusting device comprises a plurality of adjusting branches.

7. The wet etching equipment according to claim 5, further comprising a reservoir, an etching solution recovery device, and an etching branch, wherein
the reservoir is configured to store the etching solution, which comprises an input port configured to input the etching solution and an output port configured to output the etching solution;
the etching solution recovery device is connected to the input port of the reservoir, and is configured to recycle the etching solution sprayed by the sprinkler to the reservoir;
an input port of the etching branch and an input port of the adjusting branch are communicated with the output port of the reservoir, and an output port of the etching branch and an output port of the adjusting branch are communicated with the sprinkler, a second valve being further provided in the etching branch and configured to adjust a flow rate of the etching solution upon etching a metal to be etched.

8. The wet etching equipment according to claim 7, wherein the etching solution recovery device comprises an etching chamber and a return line connecting the etching chamber with the input port of the reservoir, the sprinkler being arranged inside the etching chamber.

9. The wet etching equipment according to claim 1, further comprising a filter configured to filter the etching solution inputted to the sprinkler.

10. The wet etching equipment according to claim 1, further comprising a metal ion concentration detecting device configured to detect the concentration of the metal ions in the etching solution.

11. The wet etching equipment according to claim 1, further comprising a controller configured to control the metal ion concentration adjusting device to adjust the concentration of the metal ions in the etching solution so that the concentration of the metal ions in the etching solution reaches a preset value, and then to spray the adjusted etching solution onto the metal to be etched with the sprinkler.

12. A wet etching method, comprising steps as follows:
adjusting a concentration of metal ions in an etching solution so that an etching rate of a metal to be etched is kept stable;
spraying the adjusted etching solution onto the metal to be etched.

13. The wet etching method according to claim 12, wherein, before the step of spraying the adjusted etching solution onto the metal to be etched, it further comprises a step of:
detecting the concentration of the metal ions in the adjusted etch solution, and
spraying the adjusted etching solution onto the metal to be etched in a case that the concentration of the metal ions in the adjusted etching solution reaches a preset value.

14. The wet etching method according to claim 13, wherein the metal ions compromise Cu ions, and the preset value is greater than or equal to 300 ppm.
